(19) United States
(12) Patent Application Publication
(10) Pub. No.: US 2008/0115028 A1
(43) Pub. Date: May 15, 2008

(54) METHOD AND SYSTEM FOR TEST VERIFICATION OF INTEGRATED CIRCUIT DESIGNS

(75) Inventors: Johnny Thurman Homer, Plano, TX (US); William Milton Hurley, Murphy, TX (US); Randolph Wayne Zoch, Garland, TX (US)

Correspondence Address: FOGG & POWERS LLC, 10 SOUTH FIFTH STREET, SUITE 1000, MINNEAPOLIS, MN, 55402, US

(73) Assignee: Samsung Electronics Co., Ltd., Suwon-city (KR)

(21) Appl. No.: 11/551,940

(22) Filed: Oct. 23, 2006

(51) Int. Cl. G01R 31/28; G06F 11/00

(52) U.S. Cl. 714/741

(57) ABSTRACT

A method and system for verifying the design of an integrated circuit including an analog portion and a digital portion are disclosed. As one example, a method for verifying the design of an integrated circuit is disclosed, which includes the steps of generating an analog stimulus, performing a simulation test of the analog portion of the integrated circuit using the analog stimulus as an input, collecting data at an output of the analog portion of the integrated circuit, generating a digital stimulus with the collected data, performing a simulation test of the digital portion of the integrated circuit using the digital stimulus as an input, validating data at an output of the digital portion of the integrated circuit, regression testing the digital portion of the integrated circuit using the digital stimulus as an input, and comparing a result of the regression testing step with a result of the validating data step.

### FIELD OF THE INVENTION

The invention is related to the design test and verification field, and particularly, but not exclusively, to a method and system for test verification of integrated circuit (IC) designs.

### BACKGROUND OF THE INVENTION

The continuing advancement of the mixed signal (analog and digital) application-specific IC (ASIC) design field, and the encroachment of digital signal processing into the conventional wireless Radio Frequency IC (RFIC) field, has resulted in relatively lengthy and costly corresponding analog and digital simulations being performed, in order to verify the designs of the devices involved. Furthermore, the analog stimulus generation for the simulations performed, and the simulation of the analog portions of the devices involved, typically dominate the costs (e.g., EDA tool costs, simulation times, CPU machine loading, etc.) incurred to prove the functionality of each design under test. Therefore, it would be advantageous to be able to isolate the digital signal processing and digital logic portions of a design from the analog portions, in order to optimize the digital simulation times, CPU loading requirements, and tool costs required to perform the design verification tests, and thus minimize the total non-recurring engineering (NRE) and capital expenses needed to implement and verify a mixed signal IC.

Design verification requirements that rely solely on the results of mixed analog and digital simulations typically require designers to license expensive software and/or hardware tools and also incur the “costs” associated with lengthy run-times. These problems are compounded significantly once a design has matured enough to perform the regression testing needed to identify design errors and verify corner case functionality. Designers typically attempt to offset the copious numbers of regression test simulation runs needed by parallelizing the regression runs being performed, which results in the need for multiple licenses for the additional simulation tools and test machines used. However, this design technique of parallelizing the analog and/or mixed signal simulations is prohibitive because of the relatively high costs of the tool and test machine licenses required. As such, the designers' inability to parallelize the analog and/or mixed signal simulations, due to the exorbitant licensing costs incurred, results in increased simulation run-times of an order of magnitude over those of the digital regression simulations alone. Unfortunately, the compromising of a manufacturer's capital expenditures for additional tool licenses and simulation machines can cause one of two serious problems: 1) either the devices under test arrive late to market; or 2) a device is manufactured for a design that has not been fully verified, which increases the chances that the device would have to be redesigned due to a functional error. Therefore, a technique is needed for thoroughly regressing the digital signal processing and control logic of an IC, without incurring corresponding analog and/or mixed signal testing costs.

### SUMMARY OF THE INVENTION

In one example embodiment, a method for verifying the design of an integrated circuit including an analog portion and a digital portion is provided. The method includes the steps of generating an analog stimulus, performing a simulation test of the analog portion of the integrated circuit using the analog stimulus as an input, collecting data at an output of the analog portion of the integrated circuit, generating a digital stimulus with the collected data, performing a simulation test of the digital portion of the integrated circuit using the digital stimulus as an input, validating data at an output of the digital portion of the integrated circuit, regression testing the digital portion of the integrated circuit using the digital stimulus as an input, and comparing a result of the regression testing step with a result of the validating data step.

In a second example embodiment, a method for verifying the design of a mixed signal Radio Frequency Integrated Circuit is provided. The method includes the steps of generating a first test data set, simulating a plurality of analog components of the mixed signal Radio Frequency Integrated Circuit using the first test data set as an input, responsive to the step of simulating the plurality of analog components, outputting a second test data set, simulating a plurality of digital components of the mixed signal Radio Frequency Integrated Circuit using the second test data set as an input, responsive to the step of simulating the plurality of digital components, outputting a third test data set, validating the third test data set, regression testing the plurality of digital components using the second test data set as an input, responsive to the regression testing step, outputting a fourth test data set, and comparing the fourth test data set with the third test data set.

In a third example embodiment, a system for verifying the design of an integrated circuit is provided. The system includes an analog portion of the integrated circuit, a digital portion of the integrated circuit coupled to the analog portion, and a processor unit coupled to the analog portion and the digital portion. The processor unit is operable to generate an analog stimulus, perform a simulation test of the analog portion of the integrated circuit using the analog stimulus as an input, collect data at an output of the analog portion of the integrated circuit, generate a digital stimulus with the collected data, perform a simulation test of the digital portion of the integrated circuit using the digital stimulus as an input, validate data at an output of the digital portion of the integrated circuit, regression test the digital portion of the integrated circuit using the digital stimulus as an input, and compare a result of the regression testing operation with a result of the validating data operation.

### BRIEF DESCRIPTION OF THE DRAWINGS

The novel features believed characteristic of the invention are set forth in the appended claims. The invention itself, however, as well as a preferred mode of use, further objectives and advantages thereof, will best be understood by reference to the following detailed description of an illustrative embodiment when read in conjunction with the accompanying drawings, wherein:

FIG. 1 depicts a block diagram of a method for test verification of the design of an analog and/or mixed signal IC, which can be used to implement a preferred embodiment of the present invention; and

FIG. 2 depicts an example of a design for a mixed signal (analog and digital) IC, which illustrates a use of the present invention.

### DETAILED DESCRIPTION OF PREFERRED EMBODIMENT

In an illustrative embodiment, a method is provided for optimizing the test verification of the design of an IC having substantial analog and digital portions. Essentially, the digital portions of the design are isolated to perform heavy regression testing, without incurring the costs (in both time and capital) typically associated with the numerous simulations of the analog and/or mixed signal portions of the designs. Consequently, the digital processing part of the design can be verified in a less-costly digital-only verification environment, but with a functional coverage that is virtually equivalent to that of the full mixed-signal environment for each regression test run that occurs.

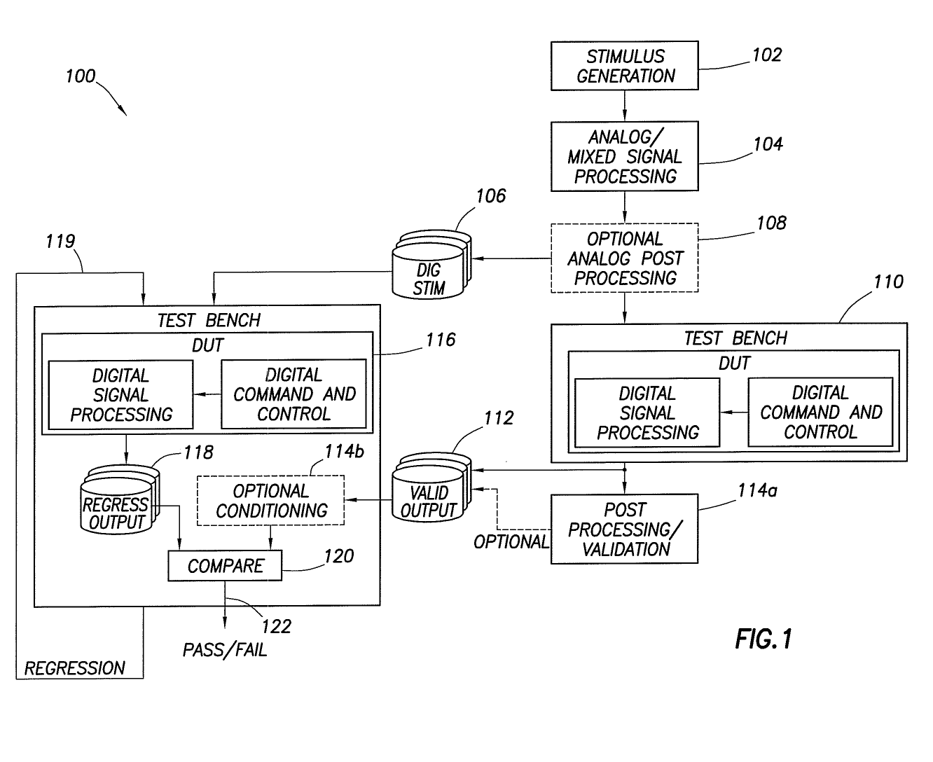

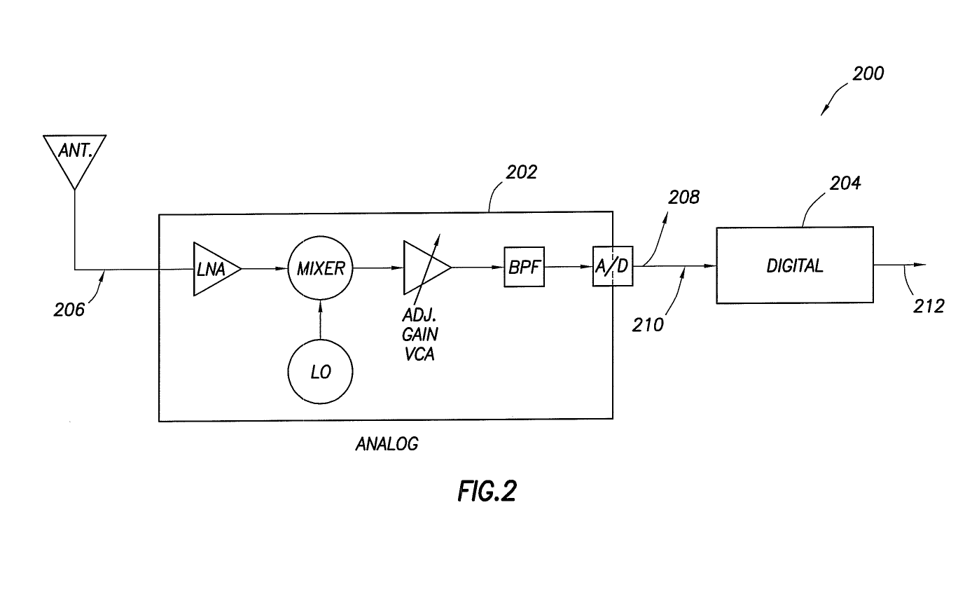

With reference now to the figures, FIG. 1 depicts a block diagram of a method 100 for test verification of the design of an analog and/or mixed signal IC, which can be used to implement a preferred embodiment of the present invention. Essentially, method 100 separates the test verification of the analog and/or mixed signal IC design into its analog and digital components, so that the digital simulation inputs and outputs can be suitably isolated for mass regression testing. For clarity and ease of understanding, FIG. 2 depicts an example of a design for a mixed signal (analog and digital) IC 200, which illustrates a use of the present invention. For example, IC 200 may be an RFIC design for a wireless receiver, which includes an analog portion 202 and a digital portion 204. As shown, the analog portion 202 of IC 200 includes typical receiver components, such as an antenna, low noise amplifier (LNA), mixer, local oscillator (LO), adjustable gain voltage-controlled amplifier (VCA), bandpass filter, and an analog-to-digital (A/D) converter. The digital portion 204 of IC 200 may include, for example, a baseband modem, host controller/processor, memory, and other typical components of a digital portion of a mixed signal IC design.

Referring now to FIGS. 1 and 2, method 100 begins with a designer/test operator generating a suitable analog test stimulus (step 102). For example, in the early stages of an IC's design, a designer/tester may generate an appropriate analog test stimulus using a known high-level analog simulation or computer modeling tool (e.g., using MATLAB, Simulink, or similar other algorithm modeling tool). Next, the operator inputs the generated analog stimulus to the analog portion 202 of the IC design involved (step 104). For this example embodiment, the operator may inject the generated analog stimulus at the front-end of the analog portion 202, such as the point indicated by the arrow designated as number 206. Specifically, for design verification purposes, the analog stimulus can be applied to the analog models of the components of analog portion 202, and simulated in a suitable analog and/or mixed signal simulator. In the early design stages, valid outputs can be generated by simulating the analog signal processing models with suitable digital simulation models. At the boundary between the analog and digital models of the design, the simulation data can be captured for use, for example, in a Register Transfer-Level (RTL) digital-only simulator (e.g., ModelSim, NC-Sim, VCS, or similar other digital simulator). Correspondingly, as described in more detail below, the output of the digital model can be captured to be used as the valid output for comparison with the digital-only RTL regression simulations.

For this example embodiment, the resulting data from the analog and/or mixed signal test simulation using the generated analog stimulus is output from the analog portion 202 (step 106). This output of the analog and/or mixed signal simulation, which is indicated by the arrow designated as number 208, may be collected directly for use as a digital stimulus if the output data is provided in a suitable format (e.g., digitized by an A/D converter). As an (optional) alternative, the analog output results of the simulation may be post-processed into a suitable digital format (step 108) such as, for example, by re-sampling and digitizing the simulation results for varying digital processing clock rates, filtering the simulation results to account for different characteristics of the analog-to-digital boundary, level-shifting the simulation results to reflect voltage differences between the analog and digital domains, converting the simulation results from floating-point to fixed-point data, and/or adding event triggers to the simulation results to aid in the synchronization of the subsequent digital simulation. Also, suitable post-processing of the analog results of the simulation may include formatting the data file so that it can be read and readily understood by the components of the digital test-bench involved. The above-described pre-digital simulation processing steps (indicated by step 108) may be repeated as often as required to generate a sufficient number of digital stimulus data sets to verify the design. For example, these digital stimulus data sets may be generated once and then used repeatedly during the massive digital test regression runs, which results in significant savings in simulation setup and run-time because the analog and/or mixed signal simulators do not have to be used.

Next, each digital stimulus data set is fed through the digital portion 204 of the IC design involved (step 110). For this example embodiment, the injection or input of the digital stimulus data is indicated by the arrow designated as number 210. The digital simulation may include testing of both the digital signal processing components/functions and the digital command and control components/functions of the IC design involved. During this step, the output of the simulation for each digital stimulus data set (e.g., indicated by the arrow designated as number 212) may be collected and validated, and provided as a validated output (step 112). Notably, for this example embodiment, the validated output data may be considered as a “golden reference” in typical simulation terms. The digital simulation outputs may be validated by, for example, analyzing the output data set for suitable bit error rates, error vector magnitudes (EVMs), or signal-to-noise ratios (SNRs). As an (optional) alternative, the validated digital simulation data sets also may be post-processed to facilitate validity checking (steps 114a, 114b). This post-processed output conditioning may include, but not be limited to, scaling the values of the output data, time-shifting the output data to synchronize the files, and/or re-synchronizing the output data using optional event triggers.

Notably, the above-described optional conditioning of the validated simulation output data may occur outside the digital regression simulation process. However, it may be beneficial to condition the validated output data set within the regression simulation process, in order to be able to dynamically adjust the process to differences from one regression test to another. Similar to the generation of the stimulus data sets, the verification of the output data sets may occur once and then be used repeatedly during extensive digital regression test runs, in order to achieve substantial savings in simulation setup and run-time.

Once the validated output data sets (from step 112) have been captured (and optionally conditioned, if desired), the digital portion 204 of the IC device under test (DUT) is placed into heavy regression testing (step 116) using the digital stimulus data sets derived at step 106. The regression testing should test the digital components of the DUT in all of their necessary states in order to validate the functionality of the IC device involved. The regression test output results are then collected (step 118). The output results of each regression test are compared with one of the “golden reference” validated output data sets (step 120). Depending on the specific regression test that was performed, the validated data set may have to be dynamically conditioned prior to the comparison step (e.g., optional conditioning step 114b). In any event, if the comparison of the regression and the validated output data set is successful, it may be assumed that the device functioned properly and passed that particular regression test (step 122). The regression testing may continue if desired (step 119). However, if the comparison of the regression test and the validated output data set is unsuccessful (step 120), it may be assumed that the device functioned improperly and failed that regression test.

Notably, as an option, the compare function (step 120) may be accomplished by performing a relatively complex calculation rather than a simple comparison of the data involved. However, as long as the processing costs associated with performing the compare function are less intensive or expensive than the cost to perform the analog post-processing functions, there is a net gain. Similarly, although the division of the analog and digital sections of the IC design may be blurred and indistinct looking from either direction, some digital components of the design may be excised from testing, and some minimal analog components may be included in the testing, as long as the inclusion of the analog components does not drive up the licensing costs for the project, or erase the time savings achieved during the regression testing. Essentially, inserting non-trivial analog simulation into the regression testing process will eradicate any time savings otherwise achieved.

By optimizing the time spent in the digital regression testing process, the present invention provides a method for verifying an IC design that saves substantial capital expenditures usually required for conventional multiple analog and/or mixed signal simulator licenses and simulation tools, and also reduces the total simulation time required to validate the IC design.

The description of the present invention has been presented for purposes of illustration and description, and is not intended to be exhaustive or limited to the invention in the form disclosed. Many modifications and variations will be apparent to those of ordinary skill in the art. These embodiments were chosen and described in order to best explain the principles of the invention, the practical application, and to enable others of ordinary skill in the art to understand the invention for various embodiments with various modifications as are suited to the particular use contemplated.

What is claimed is:

1. A method for verifying the design of an integrated circuit including an analog portion and a digital portion, comprising the steps of:
generating an analog stimulus;
performing a simulation test of the analog portion of the integrated circuit using the analog stimulus as an input;
collecting data at an output of the analog portion of the integrated circuit;
generating a digital stimulus with the collected data;
performing a simulation test of the digital portion of the integrated circuit using the digital stimulus as an input;
validating data at an output of the digital portion of the integrated circuit;
regression testing the digital portion of the integrated circuit using the digital stimulus as an input; and
comparing a result of the regression testing step with a result of the validating data step.

2. The method of claim 1, wherein the integrated circuit comprises an RFIC.

3. The method of claim 1, wherein the step of generating a digital stimulus comprises digitizing the data at the output of the analog portion of the integrated circuit.

4. The method of claim 1, wherein the integrated circuit includes a receiver arranged in an RFIC.

5. The method of claim 1, wherein the validating data step further comprises a step of conditioning the data at the output of the digital portion of the integrated circuit.

6. The method of claim 1, further comprising the steps of:
determining if the result of the regression testing step is substantially equal to the result of the validating data step; and
if so, determining that the integrated circuit has passed the regression testing.

7. The method of claim 1, wherein the data at the output of the analog portion of the integrated circuit is digitized with an analog-to-digital converter.

8. The method of claim 1, wherein the comparing step comprises comparing a valid output data set with a regression testing output data set.

9. The method of claim 1, wherein the validating step comprises a step of outputting a golden reference.

10. The method of claim 1, wherein the simulation test of the analog portion comprises at least one of a Matlab simulation and a Simulink simulation.

11. A method for verifying the design of a mixed signal Radio Frequency Integrated Circuit, comprising the steps of:
generating a first test data set;
simulating a plurality of analog components of the mixed signal Radio Frequency Integrated Circuit using the first test data set as an input;
responsive to the step of simulating the plurality of analog components, outputting a second test data set;
simulating a plurality of digital components of the mixed signal Radio Frequency Integrated Circuit using the second test data set as an input;
responsive to the step of simulating the plurality of digital components, outputting a third test data set;
validating the third test data set;
regression testing the plurality of digital components using the second test data set as an input;
responsive to the regression testing step, outputting a fourth test data set; and
comparing the fourth test data set with the third test data set.

12. The method of claim 11, wherein the first test data set comprises an analog stimulus data set.

13. The method of claim 11, wherein the second test data set comprises a digital stimulus data set associated with a result of the step of simulating the plurality of analog components.

14. The method of claim 11, wherein the comparing step comprises comparing a regression test output data set with a validated simulation test output data set.

15. The method of claim 11, further comprising the steps of:
determining if data included in the fourth test data set is substantially equal to data included in the second test data set; and
if so, determining that the design of the Radio Frequency Integrated Circuit has passed the regression testing.

16. A system for verifying the design of an integrated circuit, comprising:
an analog portion of the integrated circuit;
a digital portion of the integrated circuit coupled to the analog portion; and
a processor unit coupled to the analog portion and the digital portion, the processor unit operable to:
generate an analog stimulus;
perform a simulation test of the analog portion of the integrated circuit using the analog stimulus as an input;
collect data at an output of the analog portion of the integrated circuit;
generate a digital stimulus with the collected data;
perform a simulation test of the digital portion of the integrated circuit using the digital stimulus as an input;
validate data at an output of the digital portion of the integrated circuit;
regression test the digital portion of the integrated circuit using the digital stimulus as an input; and
compare a result of the regression testing operation with a result of the validating data operation.

17. The system of claim 16, wherein the integrated circuit comprises a mixed signal device.

18. The system of claim 16, wherein a simulation test operation of the processor Unit is performed with a computer model.

19. The system of claim 16, wherein the processor unit is further operable to:
determine if the result of the regression testing operation is substantially equal to the result of the validating data operation; and
if so, assume that the integrated circuit has passed the regression testing operation.

20. The system of claim 1, wherein the integrated circuit comprises an analog portion and a digital portion of a receiver subsystem of a transceiver.
